(19) United States
(12) Patent Application Publication
(10) Pub. No.: US 2020/0373315 A1
(43) Pub. Date: Nov. 26, 2020

(54) NON-VOLATILE MEMORY (NVM) STRUCTURE USING HOT CARRIER INJECTION (HCI)

(71) Applicant: QUALCOMM Incorporated, San Diego, CA (US)

(72) Inventors: Qingqing LIANG, San Diego, CA (US); George Pete IMTHURN, San Diego, CA (US); Sinan GOKTEPELI, San Diego, CA (US); Sivakumar KUMARASAMY, San Diego, CA (US)

(21) Appl. No.: 16/419,606

(22) Filed: May 22, 2019

(51) Int. Cl. H01L 27/11521; H01L 29/788; G11C 16/04; G11C 16/10; G11C 16/26; H01L 29/66

(52) U.S. Cl. CPC H01L 27/11521; H01L 29/7884; H01L 29/66825; G11C 16/10; G11C 16/26; G11C 16/045

(57) ABSTRACT

Certain aspects of the present disclosure are generally directed to non-volatile memory (NVM) and techniques for operating and fabricating NVM. Certain aspects provide a memory cell for implementing NVM. The memory cell generally includes a first semiconductor region, a second semiconductor region, and a third semiconductor region, the second semiconductor region being disposed between and having a different doping type than the first and third semiconductor regions. The memory cell also includes a fourth semiconductor region disposed adjacent to and having the same doping type as the third semiconductor region, a first front gate region disposed adjacent to the second semiconductor region, and a first floating front gate region disposed adjacent to the third semiconductor region. In certain aspects, the memory cell includes a back gate region, wherein the second semiconductor region is between the first front gate region and at least a portion of the back gate region.

### FIELD OF THE DISCLOSURE

The teachings of the present disclosure relate generally to memory cells, and more particularly, to a memory cell implemented with front and back gates.

### DESCRIPTION OF RELATED ART

Electronic devices including processors and memory are used extensively today in almost every electronic application. The processor controls the execution of program instructions, arithmetic functions, and access to memory and peripherals. In the simplest form, the processor executes program instructions by performing one or more arithmetic functions on data stored in memory.

### SUMMARY

The following presents a simplified summary of one or more aspects of the present disclosure, in order to provide a basic understanding of such aspects. This summary is not an extensive overview of all contemplated features of the disclosure, and is intended neither to identify key or critical elements of all aspects of the disclosure nor to delineate the scope of any or all aspects of the disclosure. Its sole purpose is to present some concepts of one or more aspects of the disclosure in a simplified form as a prelude to the more detailed description that is presented later.

Certain aspects of the present disclosure are generally directed to non-volatile memory (NVM) and techniques for operating and fabricating NVM.

Certain aspects provide a memory cell. The memory cell generally includes a first semiconductor region, a second semiconductor region, and a third semiconductor region, the second semiconductor region being disposed between and having a different doping type than the first and third semiconductor regions. The memory cell also includes a fourth semiconductor region disposed adjacent to and having the same doping type as the third semiconductor region, a first front gate region disposed adjacent to the second semiconductor region, and a first floating front gate region disposed adjacent to the third semiconductor region. In certain aspects, the memory cell includes a back gate region, wherein the second semiconductor region is between the first front gate region and at least a portion of the back gate region.

Certain aspects provide a method for operating a memory cell. The method generally includes applying a first voltage signal to a first semiconductor region of the memory cell, applying a reference potential to a second semiconductor region of the memory cell, driving a first front gate region of the memory cell via a second voltage signal to control current flow between the first and second semiconductor regions, the first voltage signal having a higher voltage magnitude than the second voltage signal, and applying a third voltage signal to a back gate region of the memory cell to facilitate hot carrier injection (HCI) of charge to a floating gate region of the memory cell, the third voltage signal having an opposite polarity than the first voltage signal and the second voltage signal.

Certain aspects provide a method for fabricating a memory cell. The method generally includes forming a first semiconductor region, a second semiconductor region, a third semiconductor region, and a fourth semiconductor region, the second semiconductor region being disposed between and having a different doping type than the first and third semiconductor regions, wherein the fourth semiconductor region is disposed adjacent to and has the same doping type as the third semiconductor region, forming a front gate region disposed adjacent to the second semiconductor region, forming a floating front gate region disposed adjacent to the third semiconductor region, and forming a back gate region, wherein the second semiconductor region is between the floating front gate region and at least a portion of the back gate region.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is an illustration of an exemplary system-on-chip (SoC) integrated circuit design, in accordance with certain aspects of the present disclosure.

FIG. 2 illustrates an example non-volatile memory (NVM) cell, in accordance with certain aspects of the present disclosure.

FIG. 3 illustrates an example NVM cell during a write operation of logic high, in accordance with certain aspects of the present disclosure.

FIG. 4 illustrates an example NVM cell during a write operation of logic low, in accordance with certain aspects of the present disclosure.

FIG. 5 illustrates an example NVM cell during a read operation based on detection of current through an n-type field-effect transistor (NFET) of the NVM cell, in accordance with certain aspects of the present disclosure.

FIG. 6 illustrates an example NVM cell during a read operation based on detection of current through a p-type field-effect transistor (PFET) of the NVM cell, in accordance with certain aspects of the present disclosure.

FIG. 7 illustrates an example NVM cell during a read operation using voltage sensing, in accordance with certain aspects of the present disclosure.

FIG. 8 is a flow diagram illustrating example operations for operating a memory cell, in accordance with certain aspects of the present disclosure.

FIG. 9 is a flow diagram illustrating example operations for fabricating a memory cell, in accordance with certain aspects of the present disclosure.

### DETAILED DESCRIPTION

Certain aspects of the present disclosure are generally directed to a non-volatile memory (NVM) cell, implemented using transistors having front and back gates. The back gate of the memory cell may be used to increase a hot carrier effect, allowing for a more efficient charging of a floating front gate region of the memory cell to store a logic state, as described in more detail herein. The hot carrier effect generally refers to electrons gaining sufficient kinetic energy to break through a gate oxide of a transistor of the memory cell and charging the floating front gate.

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well-known structures and components are shown in block diagram form in order to avoid obscuring such concepts.

The various aspects will be described in detail with reference to the accompanying drawings. Wherever possible, the same reference numbers will be used throughout the drawings to refer to the same or like parts. References made to particular examples and implementations are for illustrative purposes, and are not intended to limit the scope of the disclosure or the claims.

The terms “computing device” and “mobile device” are used interchangeably herein to refer to any one or all of servers, personal computers, smartphones, cellular telephones, tablet computers, laptop computers, netbooks, ultrabooks, palm-top computers, personal data assistants (PDAs), wireless electronic mail receivers, multimedia Internet-enabled cellular telephones, Global Positioning System (GPS) receivers, wireless gaming controllers, and similar personal electronic devices which include a programmable processor. While the various aspects are particularly useful in mobile devices (e.g., smartphones, laptop computers, etc.), which have limited resources (e.g., processing power, battery, size, etc.), the aspects are generally useful in any computing device that may benefit from improved processor performance and reduced energy consumption.

The term “multicore processor” is used herein to refer to a single integrated circuit (IC) chip or chip package that contains two or more independent processing units or cores (e.g., CPU cores, etc.) configured to read and execute program instructions. The term “multiprocessor” is used herein to refer to a system or device that includes two or more processing units configured to read and execute program instructions.

The term “system on chip” (SoC) is used herein to refer to a single integrated circuit (IC) chip that contains multiple resources and/or processors integrated on a single substrate. A single SoC may contain circuitry for digital, analog, mixed-signal, and radio-frequency functions. A single SoC may also include any number of general purpose and/or specialized processors (digital signal processors (DSPs), modem processors, video processors, etc.), memory blocks (e.g., ROM, RAM, flash, etc.), and resources (e.g., timers, voltage regulators, oscillators, etc.), any or all of which may be included in one or more cores.

A number of different types of memories and memory technologies are available or contemplated in the future, all of which are suitable for use with the various aspects of the present disclosure. Such memory technologies/types include dynamic random-access memory (DRAM), static random-access memory (SRAM), non-volatile random-access memory (NVRAM), flash memory (e.g., embedded multimedia card (eMMC) flash), pseudostatic random-access memory (PSRAM), double data rate synchronous dynamic random-access memory (DDR SDRAM), and other random-access memory (RAM) and read-only memory (ROM) technologies known in the art. A DDR SDRAM memory may be a DDR type 1 SDRAM memory, DDR type 2 SDRAM memory, DDR type 3 SDRAM memory, or a DDR type 4 SDRAM memory. Each of the above-mentioned memory technologies includes, for example, elements suitable for storing instructions, programs, control signals, and/or data for use in or by a computer or other digital electronic device. Any references to terminology and/or technical details related to an individual type of memory, interface, standard, or memory technology are for illustrative purposes only, and not intended to limit the scope of the claims to a particular memory system or technology unless specifically recited in the claim language. Mobile computing device architectures have grown in complexity, and now commonly include multiple processor cores, SoCs, co-processors, functional modules including dedicated processors (e.g., communication modem chips, GPS receivers, etc.), complex memory systems, intricate electrical interconnections (e.g., buses and/or fabrics), and numerous other resources that execute complex and power intensive software applications (e.g., video streaming applications, etc.).

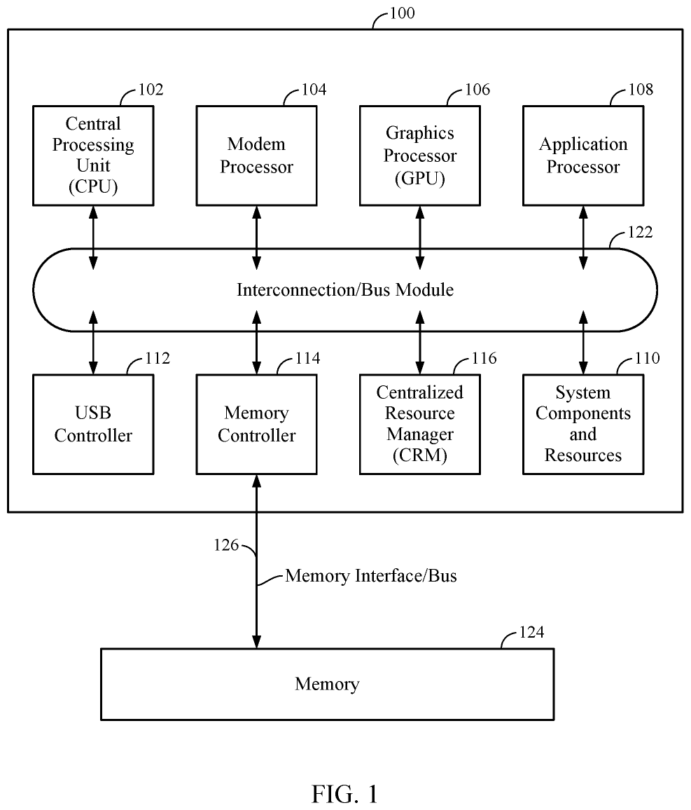

FIG. 1 illustrates example components and interconnections in a system-on-chip (SoC) 100 suitable for implementing various aspects of the present disclosure. The SoC 100 may include a number of heterogeneous processors, such as a central processing unit (CPU) 102, a modem processor 104, a graphics processor 106, and an application processor 108. Each processor 102, 104, 106, 108, may include one or more cores, and each processor/core may perform operations independent of the other processors/cores. The processors 102, 104, 106, 108 may be organized in close proximity to one another (e.g., on a single substrate, die, integrated chip, etc.) so that the processors may operate at a much higher frequency/clock rate than would be possible if the signals were to travel off-chip. The proximity of the cores may also allow for the sharing of on-chip memory and resources (e.g., voltage rails), as well as for more coordinated cooperation between cores.

The SoC 100 may include system components and resources 110 for managing sensor data, analog-to-digital conversions, and/or wireless data transmissions, and for performing other specialized operations (e.g., decoding high-definition video, video processing, etc.). System components and resources 110 may also include components such as voltage regulators, oscillators, phase-locked loops (PLLs), peripheral bridges, data controllers, system controllers, access ports, timers, and/or other similar components used to support the processors and software clients running on the computing device. The system components and resources 110 may also include circuitry for interfacing with peripheral devices, such as cameras, electronic displays, wireless communication devices, external memory chips, etc.

The SoC 100 may further include a Universal Serial Bus (USB) controller 112, one or more memory controllers 114, and a centralized resource manager (CRM) 116. The SoC 100 may also include an input/output module (not illustrated) for communicating with resources external to the SoC, each of which may be shared by two or more of the internal SoC components.

The processors 102, 104, 106, 108 may be interconnected to the USB controller 112, the memory controller 114, system components and resources 110, CRM 116, and/or other system components via an interconnection/bus module 122, which may include an array of reconfigurable logic gates and/or implement a bus architecture (e.g., CoreConnect, AMBA, etc.). Communications may also be provided by advanced interconnects, such as high performance networks on chip (NoCs).

The interconnection/bus module 122 may include or provide a bus mastering system configured to grant SoC components (e.g., processors, peripherals, etc.) exclusive control of the bus (e.g., to transfer data in burst mode, block transfer mode, etc.) for a set duration, number of operations, number of bytes, etc. In some cases, the interconnection/bus module 122 may implement an arbitration scheme to prevent multiple master components from attempting to drive the bus simultaneously.

The memory controller 114 may be a specialized hardware module configured to manage the flow of data to and from a memory 124 via a memory interface/bus 126. In certain aspects, the memory may be implemented as a non-volatile memory (NVM). Each cell of the NVM may be implemented using transistors having front and back gates, as described in more detail herein.

The memory controller 114 may comprise one or more processors configured to perform read and write operations with the memory 124. Examples of processors include microprocessors, microcontrollers, digital signal processors (DSPs), field programmable gate arrays (FPGAs), programmable logic devices (PLDs), state machines, gated logic, discrete hardware circuits, and other suitable hardware configured to perform the various functionality described throughout this disclosure. In certain aspects, the memory 124 may be part of the SoC 100.

### Example Non-Volatile Memory (NVM) Structure Using Hot Carrier Injection (HCI)

Non-volatile memory (NVM) (e.g., flash memory) is currently in high demand. A NVM cell may be implemented via a transistor having a floating gate that may be charged to adjust the threshold voltage of the transistor to store a logic state.

The floating gate may be charged via hot carrier injection (HCI). HCI (also referred to as the hot carrier effect) generally refers to electrons gaining sufficient kinetic energy to break through the gate oxide of a transistor and charging a floating gate region of the transistor.

Generally, integrating a NVM cell using a complementary metal-oxide semiconductor (CMOS) technology involves using additional masks or process steps over conventional CMOS fabrication processes, and often takes up a large area (e.g. due to peripheral circuits). Certain aspects of the present disclosure are generally directed to a NVM structure having front and back gates, which may be implemented using layer transfer technology (e.g., layer transfer silicon-on-insulator (SOI) technology). Layer transfer technology generally refers to techniques for fabricating field-effect transistors (FETs) having front and back gates. The back gate of the NVM cell may be used to increase the hot carrier effect, allowing for a more efficient charging of a floating front gate region of the NVM cell to store a logic state, as described in more detail herein. Certain aspects of the present disclosure may enable general high performance American Standard Code for Information Interchange (ASCII) radio-frequency (RF) applications.

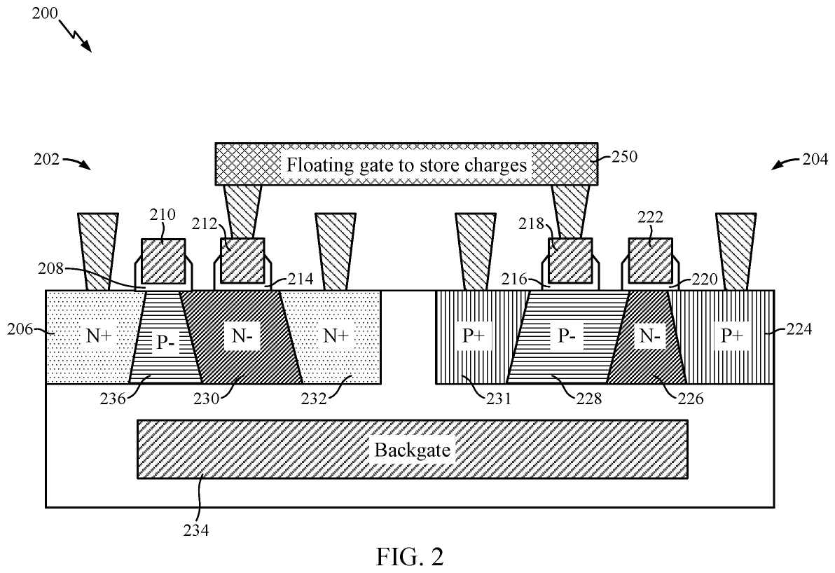

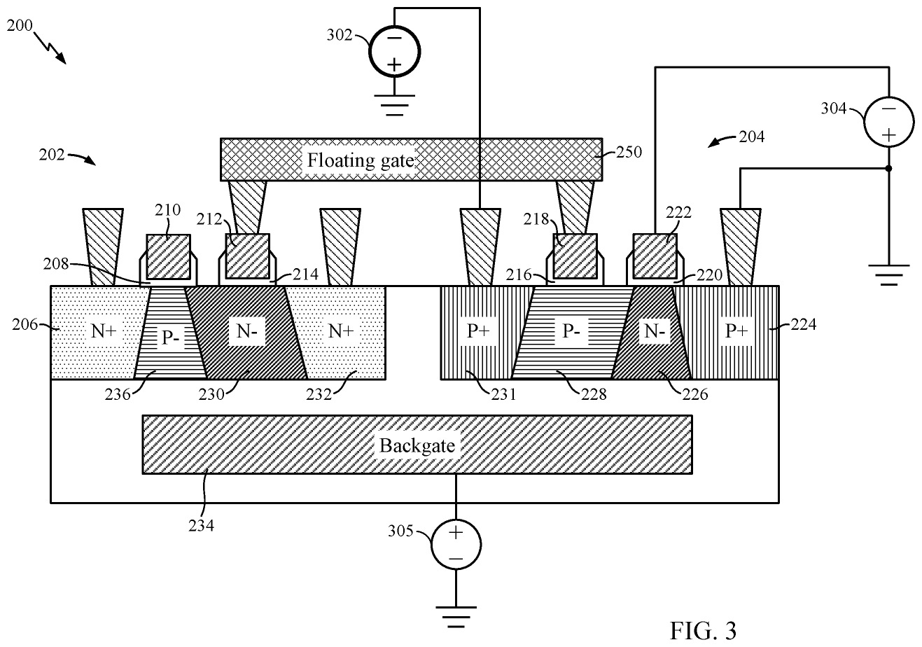

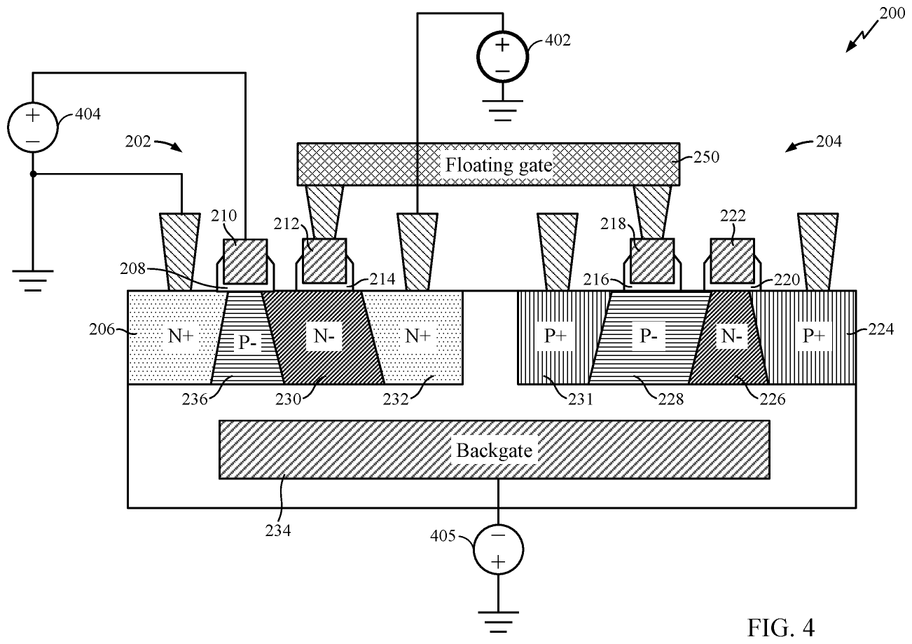

FIG. 2 is a cross-sectional view of an example NVM cell 200, in accordance with certain aspects of the present disclosure. As illustrated, the NVM cell 200 includes an n-type field-effect transistor (NFET) 202 and a p-type field-effect transistor (PFET) 204. The PFET 204 may be used to transition the logic state of the NVM cell from logic low to logic high, and the NFET may be used to transition the logic state of the NVM cell from logic high to logic low, as described in more detail with respect to FIGS. 3 and 4.

In certain aspects, the NVM cell 200 may include a back gate 234 disposed below at least portions of the NFET 202 and PFET 204. Each of the NFET 202 and the PFET includes a front gate region 210, 222. Dielectric layers 208, 220 are coupled between the front gate regions 210, 222 and channel regions 236, 226, respectively. As illustrated, the channel region 236 (e.g., semiconductor region) of the NFET 202 is implemented using a p-type (e.g., P−) semiconductor, and is between a semiconductor region 206 (e.g., source region) and a semiconductor region 232 (e.g., drain region), which are implemented using n-type (e.g., N+) semiconductor. Moreover, the channel region 226 of the PFET 204 may be implemented using an n-type (e.g., N−) semiconductor, and is between a semiconductor region 224 and a semiconductor region 231, which are implemented using p-type (e.g., P+) semiconductor.

In certain aspects, a semiconductor region 230 may be implemented between the semiconductor region 236 and the semiconductor region 232, and a semiconductor region 228 may be implemented between the semiconductor region 226 and the semiconductor region 231. A floating gate may be disposed above the semiconductor region 230 and the semiconductor region 228. For example, dielectric layers 214, 216 are disposed above the semiconductor region 230 and the semiconductor region 228, respectively. Floating front gate regions 212, 218 (e.g., front gate regions) are disposed above the dielectric layers 214, 216, respectively. In certain aspects, the floating front gate regions 212, 218 may be shorted or otherwise coupled together via a non-insulative region 250, as illustrated.

Charge may be stored in the floating front gate regions 212, 218 to adjust the characteristics of the NFET 202 and the PFET 204. For example, HCI may be used to charge and increase the potential of the floating front gate regions 212, 218, which in turn adjusts the threshold voltage (Vt) of the NFET 202 and the PFET 204, effectively writing a logic high value to the NVM cell 200. In certain aspects, the back gate 234 may be used to increase the hot carrier effect, allowing for an increased amount of charge transfer to the floating front gate regions 212, 218, as described in more detail herein.

FIG. 3 illustrates the NVM cell 200 during a write operation of logic high (e.g., charging the floating gate), in accordance with certain aspects of the present disclosure. As illustrated, voltage signals may be applied via respective voltage sources 302, 304 to the semiconductor region 231 and the front gate region 222. The voltage signal applied by the voltage source 302 may be a high voltage signal having a higher voltage magnitude than the voltage signal applied by the voltage source 304. Moreover, the semiconductor region 224 may be coupled to a reference potential node (e.g., electric ground), as illustrated. The voltage signals applied, via voltage sources 302, 304, to the semiconductor region 231 and the front gate region 222 may be negative voltage signals.

In certain aspects, a positive voltage signal may be applied to the back gate 234 via a voltage source 305 to increase the hot carrier effect, as described herein. The potential(s) of the floating front gate regions 212, 218 and the non-insulative region 250 are increased due to HCI after the voltage signals are applied via the voltage sources 302, 304, 305.

FIG. 4 illustrates the NVM cell 200 during a write operation of logic low (e.g., discharging the floating gate), in accordance with certain aspects of the present disclosure. As illustrated, voltage signals may be applied via respective voltage sources 402, 404 to the semiconductor region 232 and the front gate region 210. The voltage signal applied by the voltage source 402 may be a high voltage signal having a higher voltage than the voltage signal applied by the voltage source 404. Moreover, the semiconductor region 206 may be coupled to a reference potential node (e.g., electric ground), as illustrated. The voltage signals applied to the semiconductor region 232 and the front gate region 210 may be positive voltage signals. In certain aspects, a negative voltage signal may be applied to the back gate 234 via a voltage source 405 to increase the hot carrier effect, as described herein. The charge previously stored in the floating front gate regions 212, 218 and non-insulative region 250 is discharged after the voltage signals are applied via the voltage sources 402, 404, 405, reducing the voltage threshold of the NVM cell 200.

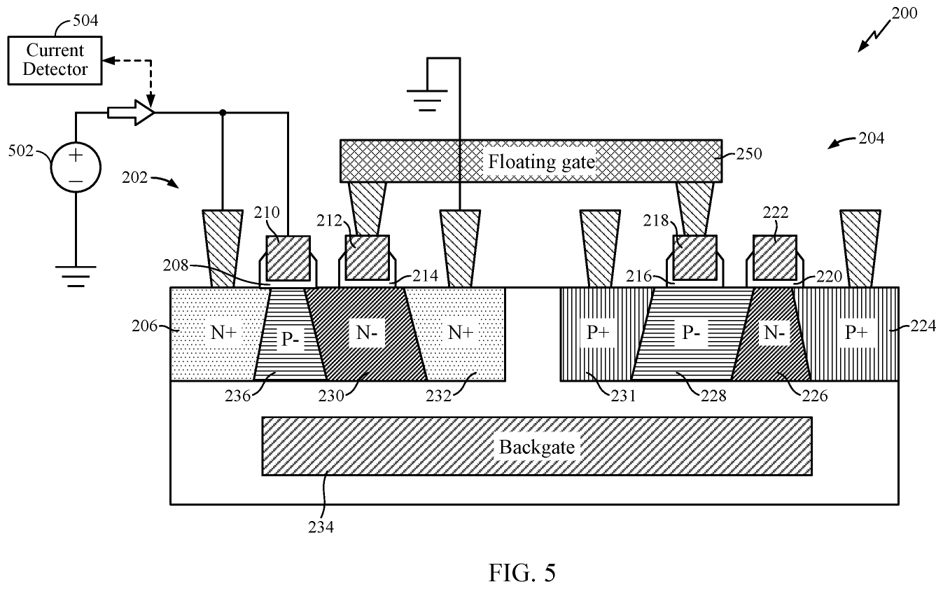

FIG. 5 illustrates the NVM cell 200 during a read operation, in accordance with certain aspects of the present disclosure. As illustrated, a voltage signal may be applied via a voltage source 502 to the semiconductor region 206 and the front gate region 210. The voltage applied by the voltage source 502 may be between the threshold voltage of the NVM cell 200 during the logic high and the logic low states of the NVM cell 200. Thus, depending on the threshold voltage of the NVM cell 200 due to the charge (or lack thereof) of the floating gate (e.g., non-insulative region 250), the current sourced by the voltage source 502 may be different, indicating the logic state of the NVM cell 200. For example, the current flowing from the semiconductor region 206 (e.g., drain region) to the semiconductor region 232 (e.g., source region) that is sourced by the voltage source 502 may be detected by the current detector 504, based on which the logic state of the NVM cell may be determined.

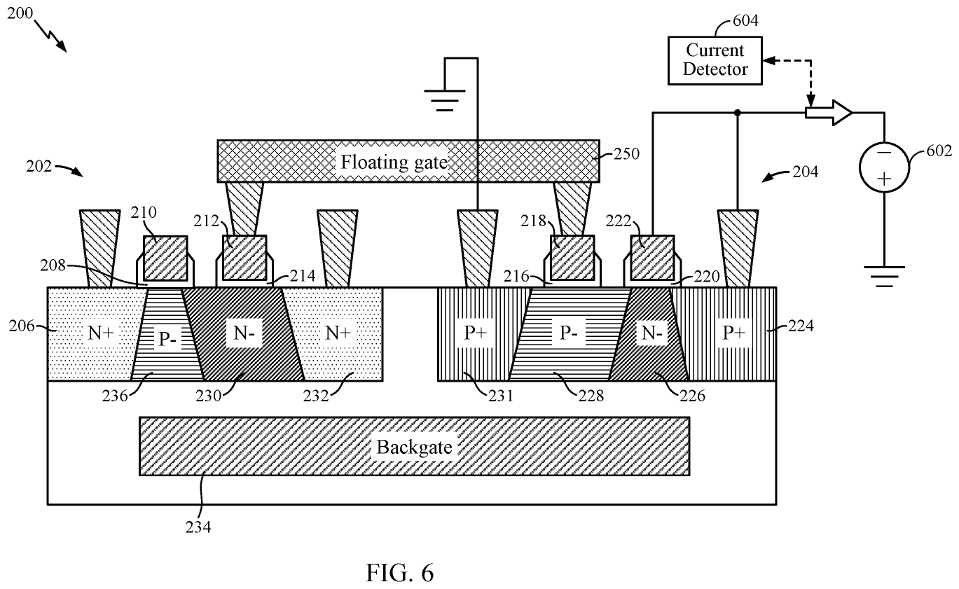

FIG. 6 illustrates the NVM cell 200 during a read operation, in accordance with certain aspects of the present disclosure. As illustrated, a voltage signal (e.g., negative voltage) may be applied via a voltage source 602 to the semiconductor region 224 and the front gate region 222. The current sunk from the semiconductor region 224 (e.g., drain region) by the voltage source 602 may be detected by the current detector 604, based on which the logic state of the NVM cell 200 may be determined.

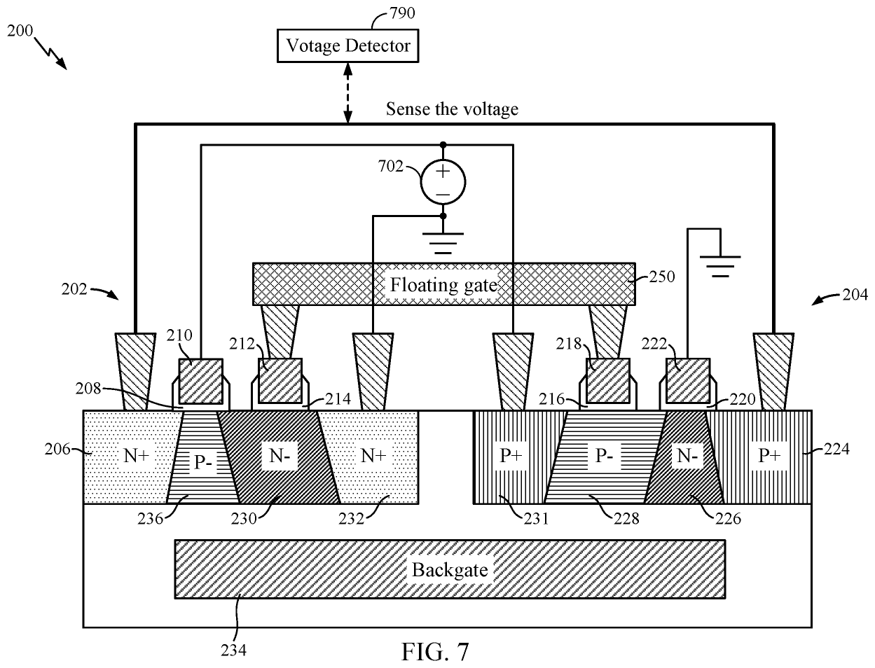

FIG. 7 illustrates the NVM cell 200 during a read operation using voltage sensing, in accordance with certain aspects of the present disclosure. As illustrated, a voltage signal may be applied to the front gate region 210 of the NFET 202 and the semiconductor region 231 (e.g., source) of the PFET 204 via a voltage source 702. Moreover, a reference potential (e.g., electric ground) may be applied to the semiconductor region 232 (e.g., source) of the NFET 202 and the front gate region 222 of the PFET 204. The semiconductor regions 206, 224 (e.g., drains) of the NFET 202 and PFET 204 may be shorted together. The voltage of the semiconductor regions 206, 224 may be sensed via a voltage detector 790, based on which the logic state of the NVM cell 200 may be determined. The voltage sources described herein (e.g., voltage sources 304, 305, 402, 404, 405, 502, 602, and/or 702) may be part of the memory controller 114.

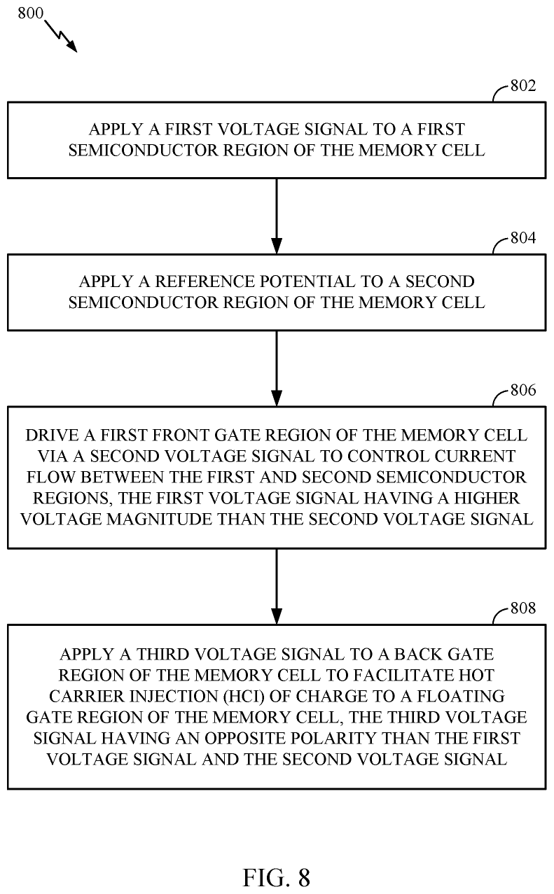

FIG. 8 is a flow diagram illustrating example operations 800 for operating a memory cell (e.g., NVM cell), in accordance with certain aspects of the present disclosure. The operations 800 may be performed by a memory control system, such as the memory controller 114 and/or voltages sources 304, 305, 402, 404, 405, 502, 602, 702.

The operations 800 begin, at block 802, with the memory control system applying a first voltage signal to a first semiconductor region (e.g., semiconductor region 231) of the memory cell, at block 804, applying a reference potential to a second semiconductor region (e.g., semiconductor region 224) of the memory cell, and at block 806, driving a first front gate region (e.g., front gate region 222) of the memory cell via a second voltage signal to control current flow between the first and second semiconductor regions. In certain aspects, the first voltage signal may have a higher voltage magnitude than the second voltage signal. The operations 800 may also include, at block 808, applying a third voltage signal to a back gate region (e.g., back gate region 234) of the memory cell to facilitate hot carrier injection (HCI) of charge to a floating gate region (e.g., floating front gate region 218) of the memory cell, the third voltage signal having an opposite polarity than the first voltage signal and the second voltage signal.

In certain aspects, the operations 800 may also include applying a fourth voltage signal to a third semiconductor region (e.g., semiconductor region 232) of the memory cell, applying a reference potential to a fourth semiconductor region (e.g., semiconductor region 206) of the memory cell, driving a second front gate region (e.g., front gate region 210) of the memory cell via a fifth voltage signal to control current flow between the third and fourth semiconductor regions, the fourth voltage signal having a higher voltage magnitude than the fifth voltage signal. In certain aspects, the operations 800 may also include applying a sixth voltage signal to the back gate region (e.g., back gate region 234) of the memory cell to facilitate discharging of the floating gate region of the memory cell, the sixth voltage signal having opposite polarity than the fourth voltage signal and the fifth voltage signal.

In certain aspects, the first semiconductor region, the second semiconductor region, the first front gate region, and the back gate region are part of a PFET (e.g., PFET 204). In certain aspects, the third semiconductor region, the fourth semiconductor region, the second front gate region, and the back gate region are part of an NFET (e.g., NFET 202).

In certain aspects, the operations 800 may also include applying a seventh voltage signal to the second front gate region and the first semiconductor region, applying the reference potential to the first front gate region and the third semiconductor region, and sensing a voltage (e.g., via voltage detector 790) at the second semiconductor region and the fourth semiconductor region while the second semiconductor region is shorted to the fourth semiconductor region. In this case, the operations 800 may also include determining a logic state corresponding to the memory cell based on the sensed voltage.

In certain aspects, the operations 800 may also include applying a fourth voltage signal to the second semiconductor region and the first front gate region of the memory cell, applying the reference potential to the first semiconductor region of the memory cell, and detecting a current (e.g., via current detector 604) sunk from the second semiconductor region when applying the fourth voltage signal and the reference potential. In this case, the operations 800 also include determining a logic state corresponding to the memory cell based on the detection of the current.

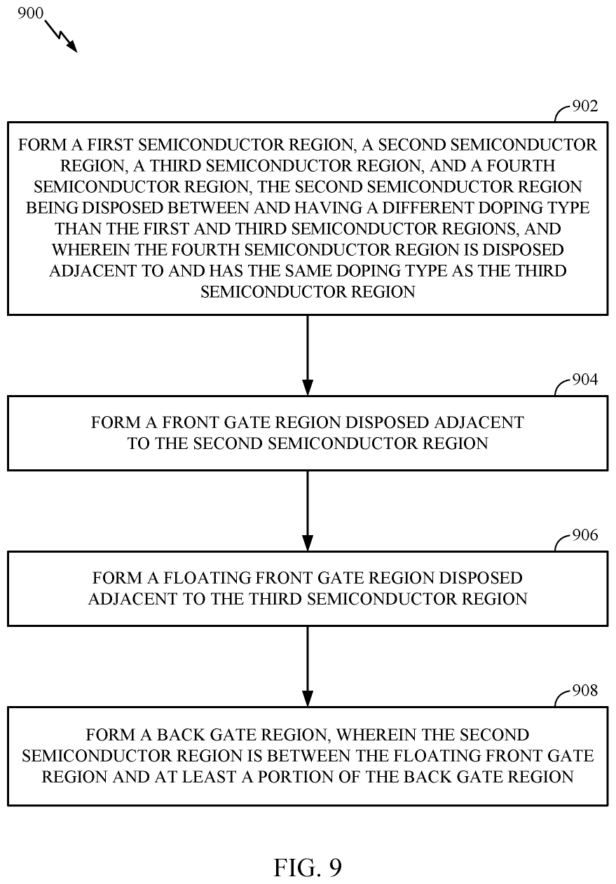

FIG. 9 is a flow diagram illustrating example operations 900 for operating a memory cell (e.g., NVM cell), in accordance with certain aspects of the present disclosure. The operations 900 may be performed by a semiconductor fabrication chamber.

The operations 900 begin, at block 902, with the chamber forming a first semiconductor region (e.g., semiconductor region 224), a second semiconductor region (e.g., semiconductor region 226), a third semiconductor region (e.g., semiconductor region 228), and a fourth semiconductor region (e.g., semiconductor region 231), the second semiconductor region being disposed between and having a different doping type than the first and third semiconductor regions. In certain aspects, the fourth semiconductor region is disposed adjacent to and has the same doping type as the third semiconductor region. The operations 900 also include, at block 904, the chamber forming a front gate region (e.g., front gate region 222) disposed adjacent to the second semiconductor region, and at block, 906, forming a floating front gate region (e.g., floating front gate region 218) disposed adjacent to the third semiconductor region. At block 908, a back gate region (e.g., back gate region 234) is formed, wherein the second semiconductor region is between the floating front gate region and at least a portion of the back gate region.

Certain aspects of the present disclosure provide an NVM structure in layer-transfer SOI technology. The modulated hot-carrier-injection as described herein is used as the main programming current and allows for an increase of write/read speed, and improving voltage limitations of the NVM.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B and object B touches object C, then objects A and C may still be considered coupled to one another—even if objects A and C do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuits.

The apparatus and methods described in the detailed description are illustrated in the accompanying drawings by various blocks, modules, components, circuits, steps, processes, algorithms, etc. (collectively referred to as “elements”). These elements may be implemented using hardware, for example.

One or more of the components, steps, features, and/or functions illustrated herein may be rearranged and/or combined into a single component, step, feature, or function or embodied in several components, steps, or functions. Additional elements, components, steps, and/or functions may also be added without departing from features disclosed herein. The apparatus, devices, and/or components illustrated herein may be configured to perform one or more of the methods, features, or steps described herein. The algorithms described herein may also be efficiently implemented in software and/or embedded in hardware.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover at least: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

What is claimed is:

1. A memory cell comprising:
a first semiconductor region;
a second semiconductor region;
a third semiconductor region, the second semiconductor region being disposed between and having a different doping type than the first and third semiconductor regions;
a fourth semiconductor region disposed adjacent to and having the same doping type as the third semiconductor region;
a first front gate region disposed adjacent to the second semiconductor region;
a first floating front gate region disposed adjacent to the third semiconductor region; and
a back gate region, wherein the second semiconductor region is between the first front gate region and at least a portion of the back gate region.

2. The memory cell of claim 1, wherein the third semiconductor region has less doping concentration than the fourth semiconductor region.

3. The memory cell of claim 1, further comprising:
a fifth semiconductor region having a different doping type than the first semiconductor region;
a sixth semiconductor region;
a seventh semiconductor region, the sixth semiconductor region being disposed between and having a different doping type than the fifth and seventh semiconductor regions;
an eighth semiconductor region disposed adjacent to and having the same doping type as the seventh semiconductor region;
a second front gate region disposed adjacent to the sixth semiconductor region; and
a second floating front gate region disposed adjacent to the seventh semiconductor region.

4. The memory cell of claim 3, wherein:
the first semiconductor region, the second semiconductor region, the third semiconductor region, the fourth semiconductor region, the first front gate region, and the first floating front gate region are part of a p-type field-effect transistor (PFET); and
the fifth semiconductor region, the sixth semiconductor region, the seventh semiconductor region, the eighth semiconductor region, the second front gate region, and the second floating front gate region are part of a n-type field-effect transistor (NFET).

5. The memory cell of claim 3, wherein the sixth semiconductor region is between the first front gate region and at least another portion of the back gate region.

6. The memory cell of claim 3, further comprising a non-insulative region, wherein the first floating front gate region is coupled to the second floating front gate region via the non-insulative region.

7. An apparatus comprising the memory cell of claim 3, the apparatus comprising a memory controller coupled to the memory cell, the memory controller being configured to:
apply a first voltage signal to the fourth semiconductor region of the memory cell;
apply a reference potential to the first semiconductor region of the memory cell;
drive the first front gate region of the memory cell via a second voltage signal to control current flow between the first and fourth semiconductor regions, the first voltage signal having a higher voltage magnitude than the second voltage signal; and
apply a third voltage signal to the back gate region of the memory cell to facilitate hot carrier injection (HCI) of charge to the first floating front gate region of the memory cell, the third voltage signal having an opposite polarity than the first voltage signal and the second voltage signal.

8. The apparatus of claim 7, wherein the memory controller is further configured to:
apply a fourth voltage signal to the eighth semiconductor region of the memory cell;
apply the reference potential to the fifth semiconductor region of the memory cell;
drive the second front gate region of the memory cell via a fifth voltage signal to control current flow between the fifth and eighth semiconductor regions, the fourth voltage signal having a higher voltage magnitude than the fifth voltage signal; and
apply a sixth voltage signal to the back gate region of the memory cell to facilitate discharging of the first floating front gate region of the memory cell, the sixth voltage signal having opposite polarity than the fourth voltage signal and the fifth voltage signal.

9. An apparatus comprising the memory cell of claim 3, the apparatus comprising a memory controller coupled to the memory cell, the memory controller being configured to:
apply a first voltage signal to the second front gate region and the fourth semiconductor region;
apply a reference potential to the first front gate region and the eighth semiconductor region;
sense a voltage at the first semiconductor region and the fifth semiconductor region while the first semiconductor region is shorted to the fifth semiconductor region; and
determine a logic state corresponding to the memory cell based on the sensed voltage.

10. An apparatus comprising the memory cell of claim 1, the apparatus comprising a memory controller coupled to the memory cell, the memory controller being configured to:
apply a first voltage signal to the first semiconductor region and the first front gate region of the memory cell;
apply a reference potential to the fourth semiconductor region of the memory cell;
detect a current sunk from the first semiconductor region when applying the first voltage signal and the reference potential; and
determine a logic state corresponding to the memory cell based on the detection of the current.

11. The memory cell of claim 1, further comprising:
a first dielectric layer between the first front gate region and the second semiconductor region;
a second dielectric layer between the first floating front gate region and the third semiconductor region; and
a dielectric region disposed between the back gate region and the second semiconductor region.

12. The memory cell of claim 1, wherein the memory cell is configured as a non-volatile memory (NVM) cell.

13. The memory cell of claim 1, wherein the first front gate region and the back gate region are disposed on opposite sides of the second semiconductor region.

14. A method for operating a memory cell, comprising:
applying a first voltage signal to a first semiconductor region of the memory cell;
applying a reference potential to a second semiconductor region of the memory cell;
driving a first front gate region of the memory cell via a second voltage signal to control current flow between the first and second semiconductor regions, the first voltage signal having a higher voltage magnitude than the second voltage signal; and
applying a third voltage signal to a back gate region of the memory cell to facilitate hot carrier injection (HCI) of charge to a floating gate region of the memory cell, the third voltage signal having an opposite polarity than the first voltage signal and the second voltage signal.

15. The method of claim 14, further comprising:
applying a fourth voltage signal to a third semiconductor region of the memory cell;
applying the reference potential to a fourth semiconductor region of the memory cell;
driving a second front gate region of the memory cell via a fifth voltage signal to control current flow between the third and fourth semiconductor regions, the fourth voltage signal having a higher voltage magnitude than the fifth voltage signal; and
applying a sixth voltage signal to the back gate region of the memory cell to facilitate discharging of the floating gate region of the memory cell, the sixth voltage signal having opposite polarity than the fourth voltage signal and the fifth voltage signal.

16. The method of claim 15, wherein:
the first semiconductor region, the second semiconductor region, the first front gate region, and the back gate region are part of a p-type field-effect transistor (PFET); and
the third semiconductor region, the fourth semiconductor region, the second front gate region, and the back gate region are part of a n-type field-effect transistor (NFET).

17. The method of claim 15, further comprising:
applying a seventh voltage signal to the second front gate region and the first semiconductor region;
applying the reference potential to the first front gate region and the third semiconductor region;
sensing a voltage at the second semiconductor region and the fourth semiconductor region while the second semiconductor region is shorted to the fourth semiconductor region; and
determining a logic state corresponding to the memory cell based on the sensed voltage.

18. The method of claim 14, further comprising:
applying a fourth voltage signal to the second semiconductor region and the first front gate region of the memory cell;
applying the reference potential to the first semiconductor region of the memory cell; and
detecting a current sunk from the second semiconductor region when applying the fourth voltage signal and the reference potential; and
determining a logic state corresponding to the memory cell based on the detection of the current.

19. The method of claim 14, wherein the memory cell is configured as a non-volatile memory (NVM) cell.

20. A method for fabricating a memory cell, comprising:
forming a first semiconductor region, a second semiconductor region, a third semiconductor region, and a fourth semiconductor region, the second semiconductor region being disposed between and having a different doping type than the first and third semiconductor regions, wherein the fourth semiconductor region is disposed adjacent to and has the same doping type as the third semiconductor region;
forming a front gate region disposed adjacent to the second semiconductor region;
forming a floating front gate region disposed adjacent to the third semiconductor region; and
forming a back gate region, wherein the second semiconductor region is between the floating front gate region and at least a portion of the back gate region.
